(19) United States
(12) Patent Application Publication
(10) Pub. No.: US 2012/0018831 A1
(43) Pub. Date: Jan. 26, 2012

(54) LIGHT PIPE FABRICATION WITH IMPROVED SENSITIVITY

(75) Inventors: Kihong KIM, Irvine, CA (US); Desmond CHEUNG, Irvine, CA (US); Yang WU, Irvine, CA (US)

(73) Assignee: HIMAX IMAGING, INC., Grand Cayman (KY)

(21) Appl. No.: 12/839,608

(22) Filed: Jul. 20, 2010

(51) Int. Cl. H01L 31/0232; H01L 31/18

(52) U.S. Cl. 257/432; 438/70; 257/E31.127

(57) ABSTRACT

In accordance with at least some embodiments of the present disclosure, a process for fabricating a light pipe (LP) is described. The process may be configured to etch a first portion of a LP funnel in a dielectric layer of a semiconductor structure using a web etching process, wherein the dielectric layer is above a photodiode region. The process may also be configured to etch a second portion of the LP funnel in the dielectric layer subsequent to the etching of the first portion of the LP funnel, wherein the second portion of the LP funnel is etched below the first portion of the LP funnel using a dry etching process.

### BACKGROUND OF THE DISCLOSURE

1. Field of the Disclosure

Embodiments of the present disclosure relate generally to complementary metal-oxide-semiconductor (CMOS) fabrication and more specifically to the fabricating of a light pipe for a CMOS image sensor.

2. Description of the Related Art

Unless otherwise indicated herein, the approaches described in this section are not prior art to the claims in this application and are not admitted to be prior art by inclusion in this section.

Image sensors have great usages in many fields. CMOS image sensors generally consume less power and also cost less than charge-coupled devices (CCD) image sensors. As the resolution of a CMOS image sensor increases, the size of each pixel sensor in the image sensor shrinks, which may also lead to the decreasing of the size of the photosensitive element (e.g., photodiode) in each pixel sensor. As the CMOS image sensors become increasingly more sophisticated, the requirements of pixel sensitivity and angular response for each pixel sensor also increase due to increasing aspect ratio of stack height to pixel pitch.

One of the methods to improve light sensitivity and angular response of the pixel sensor is to implement a light pipe (LP) on top of the photodiode. However, conventional LP fabrication processes often lead to depth fluctuations and size variations for the LPs in the CMOS sensor. The LPs built by these conventional fabrication processes may lead to low quality pixel sensors having poor light sensitivity and poor angular response.

### BRIEF DESCRIPTION OF THE DRAWINGS

FIG. 1 shows multiple cross-section views of semiconductor structures generated by various LP fabrication processes;

FIG. 2 shows multiple cross-section views of semiconductor structures going through a LP fabrication process;

FIG. 3 shows multiple cross-section views of semiconductor structures continuing through the LP fabrication process; and

FIG. 4 shows a flow diagram of an illustrative embodiment of a process for fabricating a LP with a wide top opening.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the Figures, can be arranged, substituted, combined, and designed in a wide variety of different configurations, all of which are explicitly contemplated herein.

This disclosure is drawn, inter alia, to methods and semiconductor structures related to the fabricating of a LP on a semiconductor substrate. Throughout the disclosure, the term “light pipe” may broadly refer to a semiconductor structure above a photodiode in a pixel sensor. As a part of a pixel sensor, the LP and the photodiode may greatly increase the light sensitivity and angle response of the pixel sensor. The light pipe, or LP, may be formed by a LP funnel and LP fill material. The LP funnel may broadly refer to the sidewalls and bottom of a cylinder-shaped “well”. The empty space within the “well”, which is surrounded by the sidewalls and the bottom of the LP funnel, may be referred to as the “LP cavity.” The LP cavity may then be filled with LP fill material that allows light photons to pass through. Some example requirements for such LP fill material may include, without limitation, high optical transmission, high refractive index, or easiness for gap fill. An example LP fill material may be silicate glass. During operation, light photons may be “guided” down through the LP funnel to the bottom of the LP funnel, before reaching the photodiode.

Throughout the disclosure, the term “semiconductor structure” may broadly refer to a physical structure constructed based on a semiconductor fabrication process. For example, a fabrication process may be a multiple-step sequence of photographic and chemical processing. During the fabrication process, different electronic components are gradually created on a semiconductor wafer using various depositions and etching operations. The fabrication process may deposit a layer of material on top of other materials, or etch away material from the semiconductor structure. Throughout the disclosure, when a first layer of material is deposited “above” a second layer of material, the first layer of material may either be directly on the top of the second layer, or there might be additional material in between the first and the second layers. In other words, after the second layer of material is fabricated, additional material may be deposited on the top of the second layer before the first layer of material being deposited.

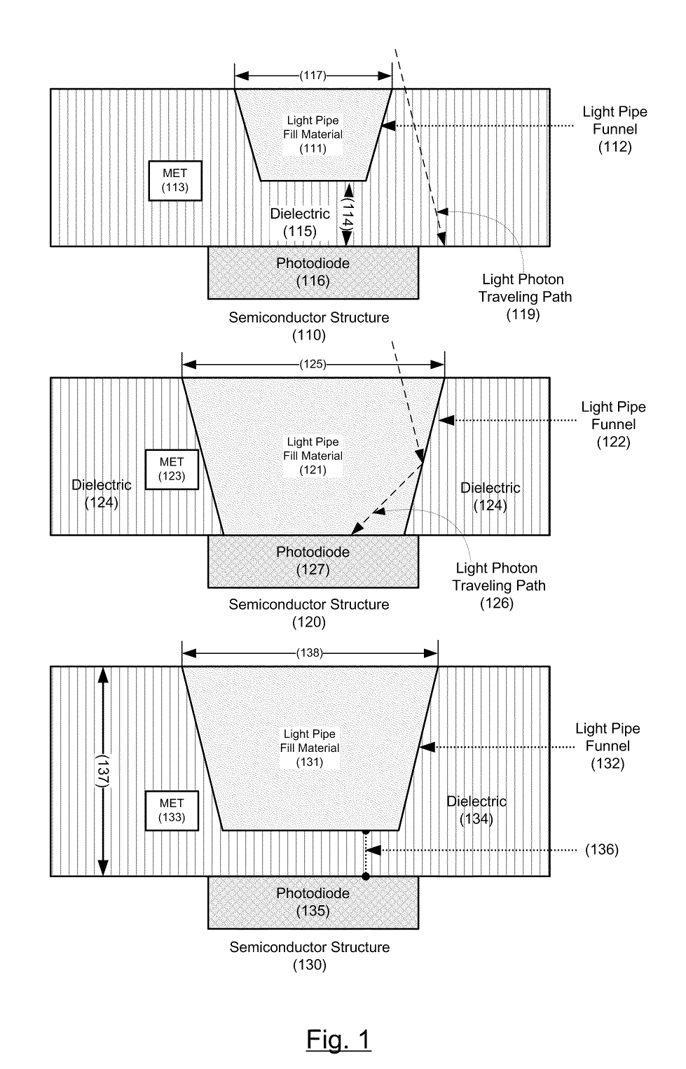

FIG. 1 shows multiple cross-section views of semiconductor structures generated by various LP fabrication processes. In FIG. 1, semiconductor structures 110, 120, and 130 may be the results of these LP fabrication processes. The semiconductor structure 110 shows an example LP having a shallow LP funnel. The semiconductor structure 120 shows another example LP having a deep LP funnel. The semiconductor structure 130 shows a further example of LP with a thick dielectric layer.

To construct the semiconductor structure 110, a photodiode region 116 may first be deposited on a semiconductor substrate (not shown in FIG. 1). Afterward, one or more dielectric layers 115 may be deposited above the photodiode region 116. In some embodiments, one or more metal lines 113 may be formed above or in between the dielectric layers 115, and other dielectric layers 115 may be formed above the metal line 113. After the dielectric layers 115 are deposited to a desired thickness, the semiconductor structure 110 may be ready for fabricating a LP funnel 112.

In some embodiments, the LP funnel 112 may be etched out of the dielectric layers 115 during an etching process. The etching process may remove the dielectric material from the dielectric layers 115, so that a cylinder-shaped cavity may be formed in the semiconductor structure 110. The cross-section view of this cylinder-shaped cavity is shown as the LP funnel 112. The diameter of a LP funnel opening 117 may be substantially the same or larger than the diameter of the bottom of the LP funnel 112. After the LP funnel 112 is formed, additional LP fill material 111 may be deposited to fill up the cavity created by the LP etching process. In some embodiments, the semiconductor structure formed by cavity and the sidewalls of the LP funnel 112 as well as the LP fill material 111 may be deemed a LP. The aforementioned LP fabrication process may also be used to fabricate the semiconductor structure 120 or the semiconductor structure 130.

In some embodiments, the photodiode region 116 may generate an electrical signal when a light photon directly strikes its surface. For example, the light photon may pass through the LP fill material 111 and/or the dielectric layers 115 before hitting the photodiode region 116. However, when a light photon travels toward the semiconductor structure 110 at an angle (as shown by a light photon traveling path 119), the light photon may miss the photodiode region 116. As a result, the photodiode region 116 may not be able to detect this light photon, even though the light photon may hit the semiconductor structure 110 at a general area above the photodiode region 116.

In some embodiments, the LP funnel 112 may allow some of the light photons that travel toward the photodiode region 116 at an angle to be reflected by the sidewalls of the LP funnel 112, and be “guided” toward the photodiode region 116. This allows the photodiode region 116 to sense the light photon that may not initially travel toward the photodiode region 116. Thus, the LP funnel 112 may improve the light sensitivity and angular response of the photodiode region 116.

In some embodiments, it may be hard to control the LP etching process during the LP fabrication process. In other words, the LP fabrication process may stop the etching of the LP funnel 112 prematurely, resulting in the LP funnel 112 that may be shallower than desired. As a result, the short sidewalls and the narrow LP funnel opening 117 of this shallow LP funnel 112 may cause fewer light photons to be reflected to the photodiode region 116. And the shallow LP funnel 112 may have an unusually thick (illustrated by a thickness 114) layer of dielectric layer at the bottom of the LP funnel 112. For example, when the thickness 114 is larger than approximately 1.3 micrometer (um), the dielectric material at the bottom of the LP funnel 112 may prevent some light photons from reaching the photodiode region 116.

Generally, a LP funnel with a wider opening may collect and reflect more light photons. As shown in the semiconductor structure 110, the light photons following the light photon traveling path 119 may not be collected by the LP funnel 112, since the LP funnel opening 117 may not be wide enough. As a result, a pixel sensor that is based on the semiconductor structure 110 may have less desirable light sensitivity and angular response than another pixel sensor that is based on a semiconductor structure having a LP funnel with a wider opening.

In some embodiments, as illustrated by the semiconductor structure 120, in order to fabricate a LP funnel 122 with a wide LP funnel opening 125, the LP fabrication process may increase the etching effort, so that more dielectric material 122 may be removed. For example, by performing an etching operation for a longer period of time, the resulting LP funnel 122 may have the wider LP funnel opening 125, comparing to the LP funnel opening 117 of the LP funnel 112. Thus, the LP funnel 122 is able to collect a light photon travelling toward a photodiode region 127 (illustrated by a light photon traveling path 126, which is at the same angle as the light photon traveling path 119). This light photon may then be reflected by the sidewall of the LP funnel 122 toward the photodiode region 127. As a result, a pixel sensor based on the semiconductor structure 120 is likely to have improved light sensitivity and angular response.

However, the long LP etching process that widens the opening of the LP funnel 122 may also remove more dielectric material from a dielectric layer 124, and leave a very thin (e.g., thinner than approximately 0.3 um) or no dielectric layer at the bottom of the LP funnel 122. Thus, this LP fabrication approach may expose the photodiode region 127 to the etching process, potentially causing the photodiode region 127 to be damaged. Also, having the LP funnel 122 being too close to the photodiode region 127 may lead to hot pixels or dark current. In addition, a metal line 123, which should be surrounded by the dielectric layer 124, may be exposed in the LP funnel 122 due to the long LP etching process. The exposed metal line 123 may touch or break the sidewall of the LP funnel 122, causing the affected sidewall to potentially reflect light less effectively. The exposing of the metal line 123 may also cause the semiconductor structure 120 to malfunction.

In some embodiments, as illustrated by the semiconductor structure 130, the LP fabrication process may generate a LP funnel 132 based on a thick dielectric layer 134. During the LP fabrication process, more dielectric material may be deposited above a photodiode region 135, so that the resulted dielectric layer 134 may have a thickness 137 that is thicker than the dielectric layer 124 of the semiconductor structure 120. Based on this thicker dielectric layer 134, the LP funnel etching process that generated the semiconductor structure 120 may also be applied, resulting in the LP funnel 132 having a wide LP funnel opening 138 and long sidewalls. In addition, there may be sufficient thickness 136 of dielectric material at the bottom of the LP funnel 132 and above the photodiode region 135. A metal line 133 may be well insulated by the dielectric layer 134.

Still, having the thicker dielectric layer 134 may have some drawbacks. For example, the thicker semiconductor structure 130 may be more expensive to manufacture, may occupy more space, and/or may have heating problems.

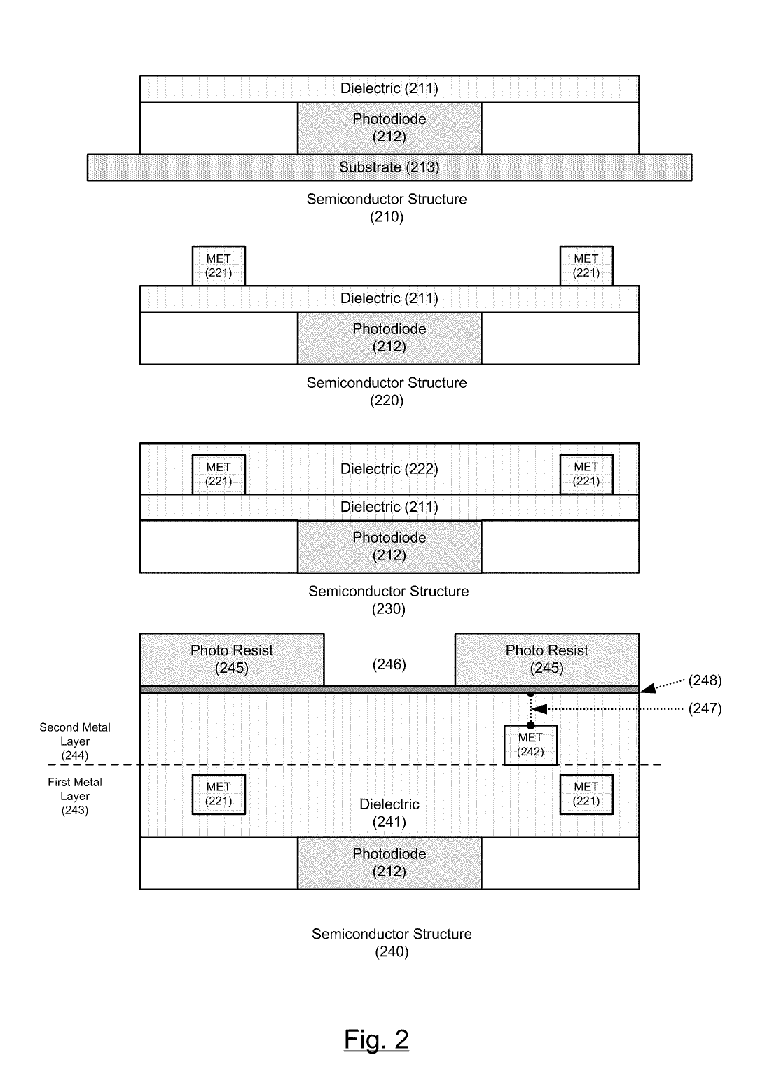

FIG. 2 shows multiple cross-section views of semiconductor structures going through a LP fabrication process, in accordance with illustrative embodiments of the present disclosure. In FIG. 2, a semiconductor structure 210 may be formed based on a set of fabrication steps. The semiconductor structure 210 may go through further depositing and etching fabrication steps to generate semiconductor structures 220, 230, and/or 240. In some embodiments, a photodiode region 212 may be formed on top of a semiconductor substrate 213. The semiconductor substrate 213 may be a part of a silicon wafer, which is formed using semiconductor materials such as silicon or germanium. The substrate 213 layer is not shown in the subsequent semiconductor structures 220, 230, and 240.

The photodiode region 212 may be deposited above the surface of the substrate 213 (as shown in FIG. 2) or be etched and formed below the surface of the substrate 213. Alternatively, the photodiode region 212 may be formed on or above other semiconductor structures. After the photodiode region 212 is formed, a dielectric layer 211 may be deposited above the photodiode region 212. In some embodiments, the dielectric layer 211 may utilize electrically insulating materials such as inter-metal dielectric (IMD) or silicon oxide.

Afterward, one or more metal lines 221 may be formed on the top of the dielectric layer 211 to generate the semiconductor structure 220. In some embodiments, the metal lines 221 may use copper, aluminium, or any other conductive metals. In the next step, another dielectric layer 222 may be formed on the top of the dielectric layer 211 and the metal lines 221. After the dielectric deposition process, a chemical mechanical polishing (CMP) may be applied to the surface of the dielectric layer 222 to flatten its surface. The result of this step may be illustrated by the semiconductor structure 230.

In some embodiments, one or more dielectric layers, and/or one or more metal lines 242 may be formed above the photodiode region 212. As illustrated by the semiconductor structures 230 and 240, the layer of structure formed by the metal lines 221, the dielectric layer 211, and the dielectric layer 222 of the semiconductor structure 230 may collectively correspond to a first metal layer 243 of the semiconductor structure 240. Since there is no additional metal line above the metal lines 221, the semiconductor structure 230 may be referred to as a one-metal pixel structure. Alternatively, one metal line 242 may be formed above the first metal layer 243, and another layer of dielectric material may be deposited to cover the metal line 242. After a CMP polishing process flattens the top surface of the semiconductor structure 240, the metal line 242 and the dielectric layer above the first metal layer 243 may be referred to as a second metal layer 244. The semiconductor structure 240 having the first metal layer 243 and the second metal layer 244 may be referred to as a two-metal pixel structure. Further, additional metal lines (not shown) may be formed above the second metal layer 244 to build a three-or-more-metal pixel structure. For illustrative purposes, the metal lines and the dielectric layers in the semiconductor structure 240 may be collectively referred to as a dielectric layer 241 hereinafter.

In some embodiments, a total thickness of the dielectric layer 241 may be adjusted by controlling a thickness 247 of the dielectric material above the top metal line (e.g., the metal line 242). In other words, by adjusting the depositing of the dielectric material and by polishing off any excessive dielectric material above the metal line 242, the total thickness of the dielectric layer 241 may be managed to prevent generating a thick-stacked pixel sensor.

In some embodiments, a light sensitive photo resist layer 245 may be formed above the dielectric layer 241. A photolithography process may use light to transform a geometric pattern from a mask to the photo resist layer 245. Subsequently, a series of chemical processing may remove some of the photo resist material from the photo resist layer 245, resulting in a LP fabrication hole 246 above a position at which a LP funnel is to be etched. The remaining photo-resist layer 245 (i.e., the photo-resist layer 245 with the LP fabrication hole 246) may be deemed as a LP mask and may also provide etch-stop control for selectively removing dielectric materials during the LP funnel etching process.

In some embodiments, the same LP mask may then be used for the subsequent etching of the LP funnel. Such an approach may simplify the LP fabrication process, reduce the fabrication costs, and improve fabrication precision. In comparison, using multiple LP masks to fabricate the different portions of the LP funnel may be more expensive and time consuming, and may also lead to misalignment among the different portions of the LP funnel. Further, as illustrated by the semiconductor structure 240, a silicon nitride layer 248 may be optionally formed above the dielectric layer 241, before the forming of the photo resist layer 245. The diameter of the LP fabrication hole 246 may depend on the designed pixel size and the layout of the pixel sensor based on the semiconductor structure 240. For a pixel sensor with 1.75 um pixel size, the diameter may be around or substantially equivalent to 1 um.

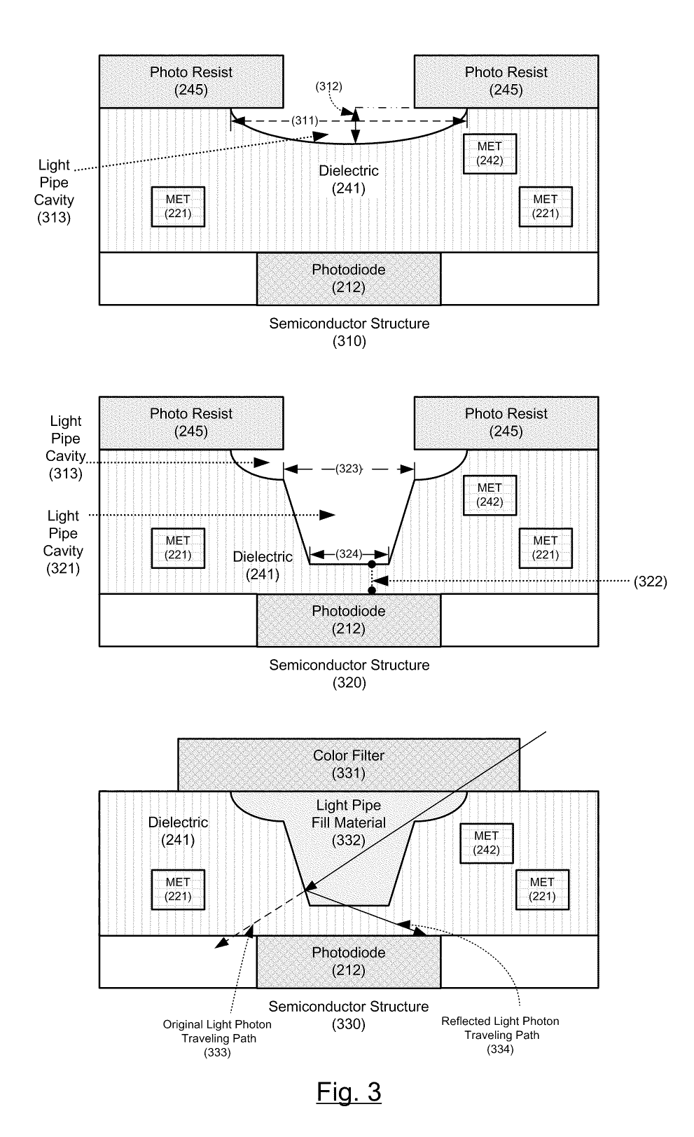

FIG. 3 shows multiple cross-section views of semiconductor structures continuing through the LP fabrication process, in accordance with illustrative embodiments of the present disclosure. Semiconductor structures 310, 320, and 330 may be built based on the two-metal pixel structure 240 of FIG. 2. During the LP fabrication process, one or more etching processes may be applied to the semiconductor structure 310, resulting in the intermediate semiconductor structures 320 and/or 330.

In some embodiments, a wet etching process may be used to remove some dielectric material from the top of the dielectric layer 241. An example wet etching process generally involves applying liquid etchant chemicals to the area of the dielectric layer 241 that is not covered by the photo resist layer 245 (e.g., the LP fabrication hole 246 of FIG. 2). The liquid etchant chemicals may react and remove the dielectric material, and create a LP cavity 313 in the dielectric layer 241. The amount of dielectric material that should be removed may be controlled approximately based on etching time and etching rate of the dielectric material under the liquid etchant chemicals.

In some embodiments, the wet etching process may be anisotropic, meaning that the rates of etching away the materials are different for different directions. For example, as illustrated by the semiconductor structure 310, the wet etching process may remove more dielectric material on the horizontal direction (illustrated by an arrow associated with a top diameter 311) than on the vertical direction (illustrated by an arrow 312). As shown by the semiconductor structure 310, the resulted LP cavity 313 may have curved or convex-like slopes. Alternatively, the wet etching process may be isotropic, meaning that the rates of etching are the same for different directions. In this case, the resulted LP cavity 313 may have round curved slopes. For a pixel sensor with 1.75 um pixel size, the top diameter 311 may be around or substantially equivalent to 1.4 um, and the height 312 may be around or substantially equivalent to 0.2 um.

Further, the wet etching process may remove dielectric material that would not be removed by a dry etching process. For example, the material underneath the photo resist layer 245, which would be protected by the photo resist layer 245 during a dry etching process, may come into contact with the liquid etchant chemicals and be removed by the wet etching process. After the wet etching process, the top diameter 311 for the top opening of the LP cavity 313 may be larger than the diameter of the LP fabrication hole (e.g., the LP fabrication hole 246) in the photo resist layer 245. Thus, the wet etching process may be useful in creating a LP with a wide opening, thereby improving the light sensitivity and angular response of the LP. However, the curved slopes of the semiconductor structure 310 created by the wet etching process may not reflect some of the light photons traveling toward the photodiode region 212.

In some embodiments, a dry etching process may be applied to the semiconductor structure 310 after the wet etching process is completed. By using the same mask that may be used for removing the material from the photo resist layer 245, the dry etching process may use plasma blasting to remove additional dielectric material from the semiconductor structure 310. The photo resist layer 245 may allow dry etching energy to be applied to a confined area (e.g., through the LP fabrication hole in the photo resist layer 245 and the LP cavity 313). As illustrated in the semiconductor structure 320, the dry etching process may create sufficient pressure to remove the dielectric material and produce the LP cavity 321 in the dielectric layer 241. The dry etching process may be anisotropic, resulting in straight slopes and edges. After the wet etching process and the dry etching process, the generated LP cavity (e.g., a combination of the LP cavity 313 and the LP cavity 321) may have a convex-shaped top portion and a cylinder-shaped bottom portion.

In some embodiments, a top diameter 323 for the top opening of the cylinder-shaped LP cavity 321 may be bigger than or substantially the same as a bottom diameter 324 of the LP cavity 321. Further, the top diameter 311 of the LP cavity 313 may be bigger than the top diameter 323. For a pixel sensor with a 1.75 um pixel size, the top diameter 323 may be around or substantially equivalent to 1 um, and the bottom diameter 324 may be around or substantially equivalent to 0.9 um. Further, the dry etching process may be controlled to ensure that it would not remove too much material from the bottom of the light pipe cavity 321. Thus, after the dry etching process, the semiconductor structure 320 may have a wide opening 311 that is comparable to the LP funnel opening 138 of FIG. 1, a bottom thickness 322 that is comparable to the bottom thickness 136 of FIG. 1. The bottom thickness 322 may have a thickness value ranging from approximately 0.4 um to 0.6 um. In some embodiments, additional etching processes (either wet or dry etching) may be performed to further etch the LP funnel.

In some embodiments, once the LP cavity 313 and the LP cavity 321 are formed, the photo resist layer 245 may be removed. In the next fabrication step, a LP fill material 332 may be used to fill the LP cavities 313 and 321. As mentioned above, the LP fill material allows light photons to pass through and strike the photodiode region 212. Once filled, the LP funnel having the LP fill material 332 and the photodiode region 212 may be used as a part of a pixel sensor for a CMOS sensor.

To achieve the desired performance, the LP fill material 332 may have a refractive index that is higher than the refractive index of the dielectric layer 241. When a light photon travels from a first medium to a second medium and hits the medium boundary, the higher the refractive index of the first medium comparing to the second medium, the lower the angle for the light photon to be reflected at the medium boundary. Thus, when a light photon travels in an original light photon travelling path 333 toward the LP funnel's sidewall, due to the difference in the refractive indexes between the LP fill material 332 and the dielectric material 241, the light photon may be reflected off the sidewall and instead travels in a reflected light photon travelling path 334 to arrive at the photodiode region 212. In other words, the greater the differences between the refractive indices of the two materials (e.g., the LP fill material 332 and the dielectric layer 241,) the more photons may be reflected off the LP funnel's sidewalls and be directed toward the photodiode region 212.

In some embodiments, the LP funnel with a wide opening may allow more light photons to be “captured” by the sidewalls of the LP funnel, and be reflected toward the photodiode region 212. For example, a light photon travelling along the original light photon travelling path 333 may not be able to travel into the LP funnel if the LP funnel's top opening is not wide enough. Instead of travelling through the LP fill 332, the light photon may be reflected or retracted by the dielectric layer 241. Thus, the aforementioned LP fabrication process may generate a LP funnel having desirable light sensitivity and angular responses, while alleviating possible dark performance issues.

In some embodiments, additional layers may be deposited above the LP funnel to server different purposes. As illustrated by the semiconductor structure 330, after the photo resist layer 245 is removed, a color filter 331 may be deposited above the LP funnel. The color filter 331 may allow light photons with a specific color to pass through, in order to build a specific color pixel sensor.

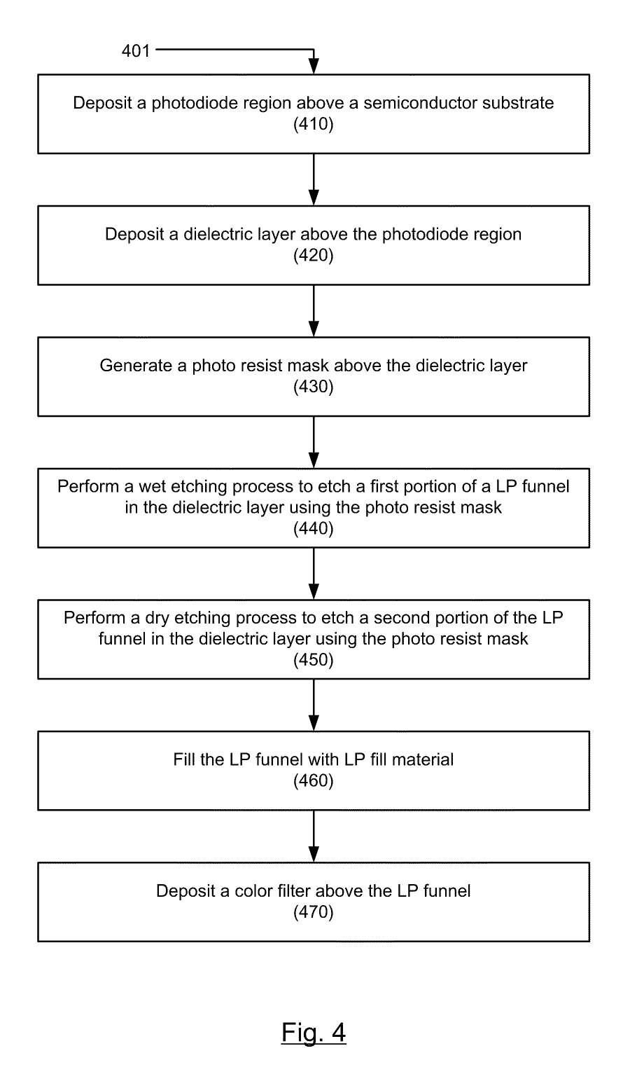

FIG. 4 shows a flow diagram of an illustrative embodiment of a process 401 for fabricating a LP with a wide top opening. The process 401 sets forth various functional blocks or actions that may be described as processing steps, functional operations, events, and/or acts, which may be performed by hardware, software, and/or firmware. Those skilled in the art in light of the present disclosure will recognize that numerous alternatives to the functional blocks shown in FIG. 4 may be practiced in various implementations.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments. Moreover, one or more of the outlined steps and operations may be performed in parallel.

At block 410, a photodiode region may be deposited above a semiconductor substrate. The photodiode region may become a part of a pixel sensor for a CMOS image sensor. At block 420, a dielectric layer may be deposited above the photodiode region. Further, one or more metal lines may be formed above the dielectric layer. In some embodiments, this operation may be optional, as the metal lines are not the essential elements for the LP funnel. Afterward, additional dielectric material may be deposited above the metal lines, and CMP polishing may flat the top surface of the dielectric layer.

At block 430, a photo resist layer may be deposited above the dielectric layer. Subsequently, photolithographic process may generate a light pipe mask on the photo resist layer. The photolithographic process may expose a LP fabrication hole on the top of the dielectric layer for the subsequent etching of a light pipe. At block 440, a wet etching process may be applied to the dielectric layer to etch a first portion of a LP funnel. The wet etching process may use the photo resist mask created at block 430. In some embodiments, the wet etching process may etch a LP cavity that has an opening that is wider than the LP fabrication hole in the light pipe mask. Further, the LP cavity created by the wet etching process may be curve-shaped or convex-shaped.

At block 450, a dry etching process may be applied to the dielectric layer to etc a second portion of the LP funnel. The dry etching process may use the same photo resist mask created at block 430, and may perform its etching operations based on the first portion of the LP funnel that has been previously wet-etched. Thus, the etched second portion of the LP funnel may be below the first portion of the LP funnel. In some embodiments, the first portion of the LP funnel may have a curved or convex shape. The second portion of the LP funnel may be cylinder-shaped. Further, the first portion of the LP funnel may have a top opening that is substantially wider than the top opening of the second portion of the LP funnel.

At block 460, the LP funnel may be filled with a type of LP fill material. In some embodiments, the LP fill material may be a type of transparent material having a high refraction index. After polishing further to remove the excess LP fill material, the result may be a desired LP having desired light sensitivity and dark performance. At block 470, a color filter may be deposited above the filled LP funnel. Afterward, the semiconductor structure may be used as a part of the pixel sensor.

Thus, methods and systems for constructing a light pipe have been described. Although the present disclosure has been described with reference to specific exemplary embodiments, it will be recognized that the disclosure is not limited to the embodiments described, but can be practiced with modification and alteration within the spirit and scope of the appended claims. Accordingly, the specification and drawings are to be regarded in an illustrative sense rather than a restrictive sense.

We claim:

1. A method for fabricating a light pipe (LP) on a semiconductor structure having a dielectric layer above a photodiode region, comprising:
etching a first portion of a LP funnel in the dielectric layer, wherein the first portion of the LP funnel is etched above the photodiode region using a wet etching process; and
etching a second portion of the LP funnel in the dielectric layer subsequent to the etching of the first portion of the LP funnel, wherein the second portion of the LP funnel is etched below the first portion of the LP funnel using a dry etching process.

2. The method as recited in claim 1, further comprising:
filling the LP funnel with LP fill material.

3. The method as recited in claim 2, further comprising:
depositing a color filter above the filled LP funnel.

4. The method as recited in claim 1, wherein the dielectric layer includes a metal line.

5. The method as recited in claim 1, wherein the etching of the first portion of the LP funnel and the etching of the second portion of the LP funnel use a same etching mask.

6. The method as recited in claim 1, wherein the first portion of the LP funnel has a convex shape.

7. The method as recited in claim 1, wherein the second portion of the LP funnel has a cylinder shape with its top diameter larger than its bottom diameter.

8. The method as recited in claim 1, wherein the wet etching process is anisotropic to etch more material on a horizontal direction in the first portion of the LP funnel than on a vertical direction.

9. A method for fabricating a light pipe (LP), comprising:
depositing a photodiode region above a semiconductor substrate;
depositing a dielectric layer above the photodiode region;
performing a wet etching process to etch a first portion of a LP funnel in the dielectric layer; and
performing a dry etching process to etch a second portion of the LP funnel in the dielectric layer subsequent to the etching of the first portion of the LP funnel.

10. The method as recited in claim 9, further comprising:
filling the LP funnel with LP fill material, wherein the LP fill material has a refraction index that is higher than a refraction index of the dielectric layer.

11. The method as recited in claim 9, further comprising:
depositing a color filter above the LP funnel.

12. The method as recited in claim 9, further comprising:
generating a photo resist mask above the dielectric layer.

13. The method as recited in claim 12, wherein the first portion of the LP funnel has a top opening that is wider than a diameter of a LP fabrication hole in the photo resist mask.

14. The method as recited in claim 9, wherein the first portion of the LP funnel is etched using the photo resist mask.

15. The method as recited in claim 9, wherein the second portion of the LP funnel is etched using the photo resist mask.

16. A semiconductor structure configured to channel light, comprising:
a photodiode region;
a dielectric layer above the photodiode region; and
a light pipe being etched from the dielectric layer, wherein a first portion of the light pipe is etched using a wet etching process, and a second portion of the light pipe is etched using a dry etching process, the second portion of the light pipe being directly below the first portion of the light pipe.

17. The semiconductor structure as recited in claim 16, further comprising:
a semiconductor substrate, wherein the photodiode region is formed on top of the semiconductor substrate.

18. The semiconductor structure as recited in claim 16, further comprising:
a color filter above the light pipe.

19. The semiconductor structure as recited in claim 16, further comprising:
a metal line being surrounded by the dielectric layer.

20. The semiconductor structure as recited in claim 16, wherein the first portion of the light pipe has a top diameter that is substantially equivalent to 1.4 um, and the second portion of the light pipe has a top diameter that is substantially equivalent to 1 um and a bottom diameter that is substantially equivalent to 0.9 um.
